(19) United States
(12) Patent Application Publication
(10) Pub. No.: US 2010/0073987 A1
(43) Pub. Date: Mar. 25, 2010

(54) SEMICONDUCTOR MEMORY DEVICE AND DRIVING METHOD OF SEMICONDUCTOR MEMORY DEVICE

(75) Inventor: Katsuhiko Hoya, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/563,010

(22) Filed: Sep. 18, 2009

(30) Foreign Application Priority Data
Sep. 24, 2008 (JP) 2008-244442

(51) Int. Cl. G11C 11/22; G11C 29/00; G11C 11/24

(52) U.S. Cl. 365/145; 365/200; 365/149

(57) ABSTRACT

A memory includes a memory cell array comprising memory cells; word lines connected to gates of the cell transistors; bit lines connected to one ends of the memory cells on the cell transistor side; plate lines connected to the other ends of the memory cells on the ferroelectric capacitor side; a sense amplifier detecting data stored in the ferroelectric capacitor; an error correcting circuit correcting error bits when such error bits exist in pieces of data; a redundancy cell array comprising redundancy cells; and a ferroelectric fuse corresponding to the redundancy cell and configured to indicate whether data is stored in the corresponding redundancy cell, wherein when error bits exist in the data read from the memory cell array, the data corrected by the error correcting circuit is written in the redundancy cell and a polarization state of the ferroelectric fuse corresponding to that redundancy cell is changed accordingly.

### CROSS-REFERENCE TO RELATED APPLICATION

This application is based upon and claims the benefit of priority from the prior Japanese Patent Applications No. 2008-244442, filed on Sep. 24, 2008, the entire contents of which are incorporated herein by reference.

### BACKGROUND OF THE INVENTION

1. Field of the Invention

The current invention relates to a semiconductor memory device and a driving method thereof.

2. Related Art

Ferroelectric memories utilize hysteresis characteristics of spontaneous polarization of ferroelectric bodies. The ferroelectric memories can store binary data in a non-volatile manner depending on the difference between two different polarization states of the ferroelectric bodies.

Many ferroelectric memories are usually provided with a redundancy function. When defective memory cells exist in memory cell arrays before shipment of memory chips, redundancy cells are used instead of normal memory cells. When the redundancy cells are used, laser fuses corresponding to these redundancy cells are processed. Thus, when an address of the defective memory cell is to be accessed, the redundancy cell can be accessed instead of the defective memory cell.

The redundancy function using laser fuses is effective for defective memory cells found in pre-shipment tests. However, the redundancy function cannot handle defective memory cells found after a user receives ferroelectric memories.

ECC (Error Correcting and Checking) circuits correct error bits in a plurality of pieces of data read from memories in order to have accurate values. The ECC circuit is effective in improving the reliability.

However, ECCs generally used for 1-bit error correction cannot correct errors of two or more bits. When ECCs capable of correcting the errors of two or more bits are used, the data detection time may be increased and circuits for memories may be extended.

### SUMMARY OF THE INVENTION

A semiconductor memory device according to an embodiment of the present invention comprises: a memory cell array comprising a plurality of memory cells, each of which comprises a cell transistor and a ferroelectric capacitor which are connected to each other serially; word lines connected to gates of the cell transistors; bit lines connected to one ends of the memory cells on the cell transistor side; plate lines connected to the other ends of the memory cells on the ferroelectric capacitor side; a sense amplifier configured to detect data stored in the ferroelectric capacitor; an error correcting circuit configured to correct error bits when such error bits exist in a plurality of pieces of data read from the memory cell array; a redundancy cell array comprising a plurality of redundancy cells, each of which comprises a cell transistor and a ferroelectric capacitor which are connected to each other serially; and a ferroelectric fuse corresponding to the redundancy cell and configured to indicate whether data is stored in the corresponding redundancy cell, wherein when error bits exist in the data read from the memory cell array, the data corrected by the error correcting circuit is written in the redundancy cell and a polarization state of the ferroelectric fuse corresponding to that redundancy cell is changed accordingly.

A method of driving a semiconductor memory device according to an embodiment of the present invention, the semiconductor memory device comprising: a memory cell array comprising a plurality of memory cells, each of which comprises a cell transistor and a ferroelectric capacitor which are connected to each other serially; word lines connected to gates of the cell transistors; bit lines connected to one ends of the memory cells on the cell transistor side; plate lines connected to the other ends of the memory cells on the ferroelectric capacitor side; a sense amplifier configured to detect data stored in the ferroelectric capacitor; an error correcting circuit configured to correct error bits when such error bits exist in a plurality of pieces of data read from the memory cell array; a redundancy cell array comprising a plurality of redundancy cells, each of which comprises a cell transistor and a ferroelectric capacitor which are connected to each other serially; and a ferroelectric fuse corresponding to the redundancy cell and configured to indicate whether data is stored in the corresponding redundancy cell,

the method comprises: reading from the memory cell by the sense amplifier; correcting error bits by the error correcting circuit when the error bits exist in the data; and writing the corrected data in the redundancy cell and changing the polarization state of the ferroelectric fuse corresponding to the redundancy cell.

### BRIEF DESCRIPTION OF THE DRAWINGS

FIG. 1 is a block diagram showing a configuration of a ferroelectric memory according to a first embodiment;

FIG. 2 shows configurations of a memory cell array MCA and peripheral parts of the first embodiment;

FIG. 3 shows a configuration of the RD controller RDC;

FIG. 4 is a conceptual diagram showing an operation of the ferroelectric memory according to the first embodiment;

FIG. 5 is a flow chart showing an operation for reading from the redundancy cell array RCA;

FIG. 6 is a timing chart showing a read operation of the ferroelectric memory according to the first embodiment;

FIG. 7 is a timing chart showing another read operation of the ferroelectric memory according to the first embodiment;

FIG. 8 is a timing chart showing a further read operation of the ferroelectric memory according to the first embodiment; and

FIG. 9 is a block diagram showing a configuration of a ferroelectric memory according to a second embodiment.

### DETAILED DESCRIPTION OF THE INVENTION

Embodiments of the present invention will be explained below in detail with reference to the accompanying drawings. Note that the invention is not limited thereto.

### First Embodiment

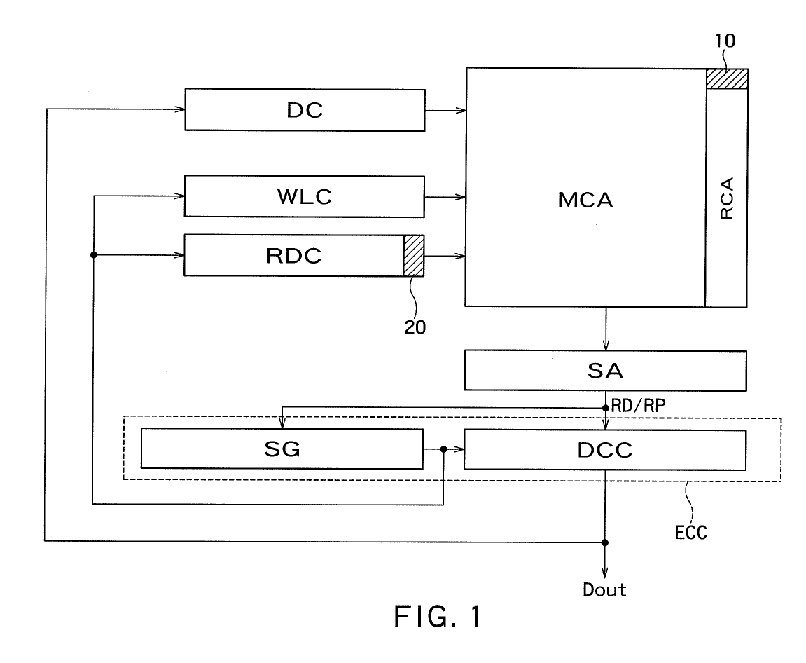

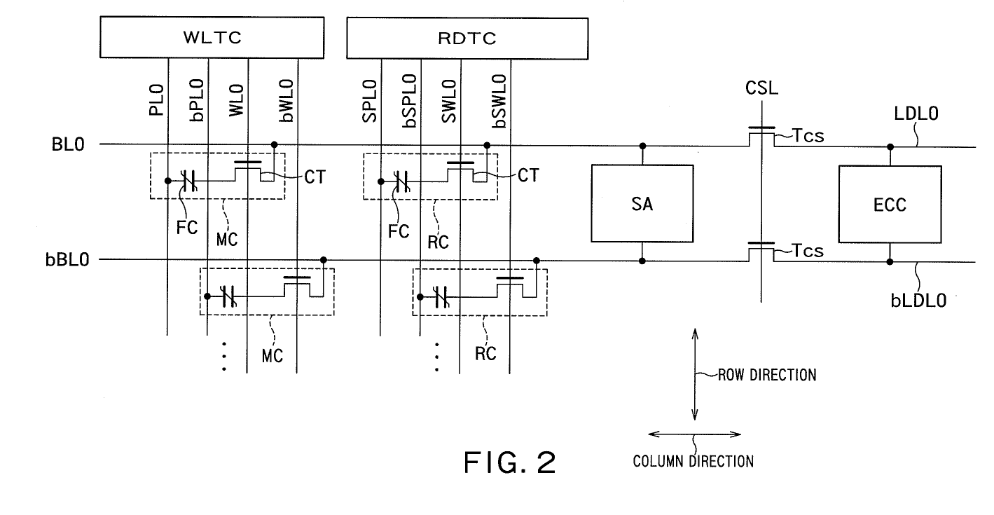

FIG. 1 is a block diagram showing a configuration of a ferroelectric memory according to a first embodiment of the present invention. FIG. 2 shows configurations of a memory cell array MCA and peripheral parts thereof.

The ferroelectric memory of the first embodiment comprises a memory cell array MCA, a redundancy cell array RCA, a data controller DC, a sense amplifier SA, a WL controller WLC, an RD controller RDC, and an error correcting circuit ECC.

The memory cell array MCA includes a plurality of memory cells MC arranged two-dimensionally in a matrix as shown in FIG. 2. The redundancy cell array RCA is configured in such a manner that redundancy cells with the same configuration as the memory cells MC are arranged two-dimensionally in a matrix. Each memory cell MC has a cell transistor CT and a ferroelectric capacitor FC connected serially to each other. A gate electrode of the cell transistor CT is connected to a word line WLi (i is an integer) or bWLi (hereinafter, also collectively WL). An end of the memory cell MC on the cell transistor CT side is connected to a bit line BLj (j is an integer) or bBLj (hereinafter, also collectively BL). The other end of the memory cell MC on the ferroelectric capacitor FC side is connected to a plate line PLi or bPLi (hereinafter, also collectively PL).

A gate electrode of the cell transistor CT in each redundancy cell is connected to a spare word line SWLi (i is an integer) or bSWLi (hereinafter, also collectively SWL). An end of the redundancy cell on the cell transistor CT side is connected to the bit line BL. The other end of the redundancy cell on the ferroelectric capacitor FC side is connected to a spare plate line SPLi or bSPLi (hereinafter, also collectively SPL).

As shown in FIG. 2, the word lines WL and the plate lines PL extend in a row direction. The plate lines PL are provided to correspond to the respective word lines WL. The spare word lines SWL and the spare plate lines SPL extend in the row direction. The spare plate lines SPL are provided to correspond to the respective spare word lines SWL. The bit lines BL extend in a column direction and are substantially perpendicular to the word lines WL, the plate lines PL, the spare word lines SWL, and the spare plate lines SPL.

The memory cell MC is provided at an intersection of the word line WL with the bit line BL. The redundancy cell is provided at an intersection of the spare word line SWL with the bit line BL.

With reference to FIG. 1, the WL controller WLC is configured to select a word line WL or word lines WL in the memory cell array MCA. The RD controller RDC is configured to select a spare word line SWL or spare word lines SWL in the redundancy cell array RCA. The memory cell array MCA and the redundancy cell array RCA share the bit lines BL. The data controller DC is configured to control data written in or read from a selected memory cell MC or a selected redundancy cell RC.

The sense amplifier SA is connected between the bit lines BLj and bBLj as shown in FIG. 2. The bit lines BLj and bBLj transmit complementary data. Thus, the sense amplifier SA detects the data stored in the ferroelectric capacitor FC by using data of either the bit line BLj or bBLj as reference data. That is, the ferroelectric memory of the first embodiment is a 2 cell/bit (2T/2C) memory storing 1 bit data in two memory cells MC.

The ECC circuit is connected between local data lines LDLj and bLDLj as shown in FIG. 2. The local data lines LDLj and bLDLj are connected via column selective transistors Tcs to the bit lines BLj and bBLj, respectively. It is assumed that the ECC circuit can correct 1-bit error.

The ECC circuit includes a syndrome generating circuit SG and a data correcting circuit DCC as shown in FIG. 1. The syndrome generating circuit SG operates information data included in read data and parity to output data used for error correction. The data correcting circuit DCC receives the data for error correction outputted from the syndrome generating circuit SG to detect error bits in the read data and correct the error bits.

The read data subjected to error correction is outputted from an input/output unit Dout of the ferroelectric memory and also transferred to the data controller DC. The data outputted from the syndrome generating circuit SG is also transferred to the WL controller WLC and the RD controller RDC.

The redundancy cell array RCA includes ferroelectric fuses 10. The ferroelectric fuse 10 has the same configuration as the memory cell MC and can hold data (flag state) depending on polarization characteristics. The ferroelectric fuses 10 are provided to correspond to the respective blocks (hereinafter, also “redundancy blocks”) each of which comprises a plurality of redundancy cells. The ferroelectric fuse 10 indicates whether the data is stored in the corresponding redundancy block by the flag state held therein. The redundancy block is a memory block in the redundancy cell RC capable of storing the same data capacity as that of a read unit block or a write unit block (hereinafter, also “memory cell block”) in the memory cell array.

The RD controller RDC includes laser fuses 20. The laser fuses 20 can be known fuses disconnecting physically interconnections by lasers. The laser fuses 20 are provided to correspond to the redundancy blocks. The redundancy blocks corresponding to the laser fuses 20 are different from the ones corresponding to the ferroelectric fuses 10. The laser fuse 20 indicates whether the data is stored in the corresponding redundancy block by its connection state (flag state).

Because the laser fuse 20 disconnects physically the interconnection, once the data is written in the redundancy block corresponding to the laser fuse 20, that data cannot be rewritten. Thus, the laser fuse 20 and the corresponding redundancy block are used instead of a memory cell block including defective memory cells in a pre-shipment test.

In contrast, because the ferroelectric fuse 10 is rewritable, the data in the redundancy block can be rewritten after shipment. Thus, even if defective memory cells are generated while a user uses such memories, the redundancy block corresponding to the ferroelectric fuse 10 can be used instead of the memory cell block including such defective memory cells.

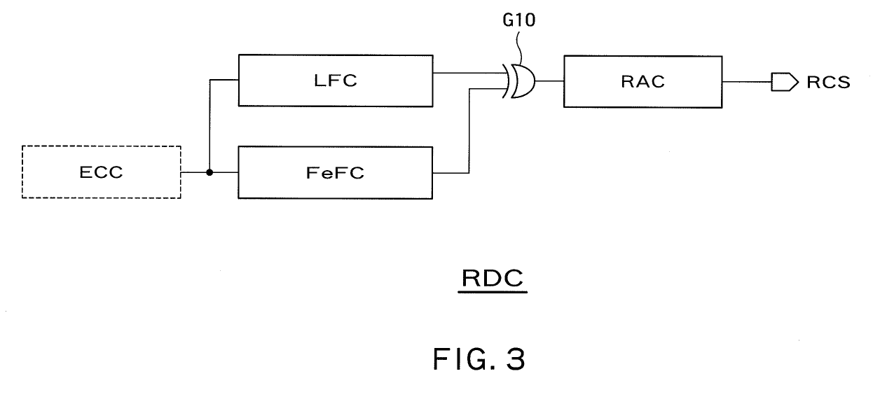

FIG. 3 shows a configuration of the RD controller RDC. The RD controller RDC includes a laser fuse controller LFC, a ferroelectric fuse controller FeFC, an exclusive OR gate G10, and a redundancy address controller RAC.

The laser fuse controller LFC and the ferroelectric fuse controller FeFC receive outputs from the syndrome generating circuit SG and output the flag state of fuses corresponding to addresses indicated by the output data. When either the laser fuse controller LFC or the ferroelectric fuse controller FeFC is activated, the redundancy address controller RAC outputs redundancy control signals RCS for selecting the redundancy blocks corresponding to the fuses. The redundancy control signal RCS drives the corresponding spare word line SWL and spare plate line SPL.

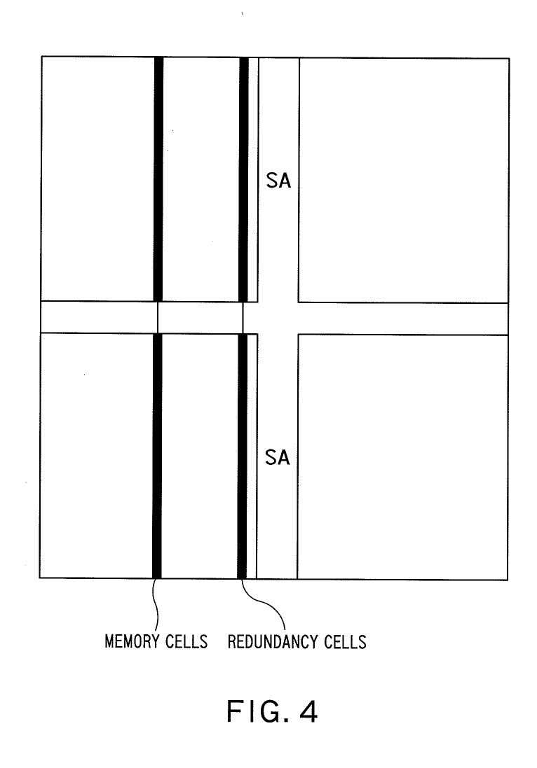

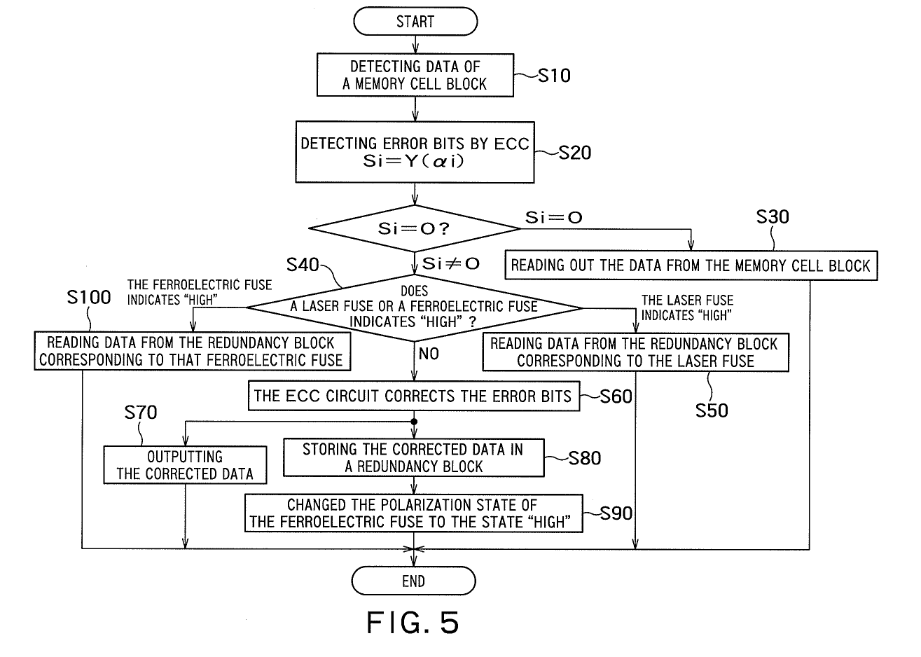

FIG. 4 is a conceptual diagram showing an operation of the ferroelectric memory according to the first embodiment. FIG. 5 is a flow chart showing an operation for reading from the redundancy cell array RCA.

As shown in FIG. 5, the data of a memory cell block in the memory cell array MCA is first detected (S10). The bit line pair BL, bBL precharged at VSS is made to be in a floating state. The selected word lines WL0 and bWL0 are made to be logically high and the ferroelectric capacitors are connected to the bit line pair BL, bBL. The voltage of the plate line PL0, bPL0 is changed from VSS to VAA (capacitor-applied voltage). The voltage VAA is thus applied to ends of the ferroelectric capacitor in the selected memory cell and an electric charge from the ferroelectric capacitor is read in the bit line. The sense amplifier SA amplifies the potential difference between the bit lines BL and bBL. Two memory cells connected to the bit line pair BL, bBL store complementary data. The sense amplifier SA detects the complementary data of the two memory cells.

Because the ferroelectric memory is a destructive read out memory, the read operation includes a rewrite (restore) operation in the same memory cell. The data detected by the sense amplifier SA is restored in the same memory cell.

The ECC circuit detects error bits of data read from the memory cell block (S20). If the error bits do not exist (Si=0), the memory performs the normal read operation. That is, the memory outputs the data from the memory cell block without any processing (S30).

If any error bits exist (Si≠0), the RD controller RDC detects the state of the laser fuse 20 (S40). If the laser fuse 20 indicates “high”, that is, the redundancy block corresponding to the laser fuse 20 is used, the sense amplifier SA reads data from the redundancy block corresponding to the laser fuse 20 (S50). The connected or disconnected state of the laser fuse 20 can be set to high or low.

If the laser fuse 20 and the ferroelectric fuse 10 indicate “low” (NO at S40), that is, if the redundancy blocks corresponding to the laser fuse 20 and the ferroelectric fuse 10 are not used, the ECC circuit corrects the error bits (S60). The corrected data is outputted from the output Dout (S70). The data corrected by the ECC circuit is also written in the redundancy cell array RCA (S80). Further, the polarization state of the ferroelectric fuse 10 corresponding to the redundancy cell in which the data is written is changed. For example, when the redundancy cell array RCA is not used, the polarization states of the ferroelectric fuses 10 are all set to the same logical state “low”. Thereafter, when any redundancy block is then used, only the polarization state of the ferroelectric fuse 10 corresponding to that redundancy block is changed to the logical state “high”.

If error bits are generated while a user uses memories, the redundancy block stores the corrected data instead of the memory cell block.

If the ferroelectric fuse 10 indicates “high”, that is, if the redundancy block corresponding to the ferroelectric fuse 10 is used, the data is read from the redundancy block corresponding to that ferroelectric fuse 10 (S100). The polarization state of the ferroelectric fuse 10 can be set to high or low.

Step S40 is performed in the RD controller RDC shown in FIG. 3. When the ferroelectric fuse 10 or the laser fuse 20 indicates that the redundancy block is used, the RD controller RDC activates the redundancy control signal RCS. Thus, an RD timing controller RDTC shown in FIG. 2 drives the spare word line SWLi and the spare plate line SPLi at a predetermined timing. When the redundancy control signal RCS is activated, the WL controller WLC shown in FIG. 1 inactivates all word lines WL corresponding to the memory cell array MCA. As a result, the sense amplifier SA can detect the data from the corresponding redundancy block.

If the ferroelectric fuse 10 or the laser fuse 20 indicates that the redundancy block is not used, the RD controller RDC inactivates the redundancy control signal RCS. Alternatively, the WL controller WLC activates selectively any of the word lines WL corresponding to the memory cell array MCA. As a result, the sense amplifier SA can detect the data from the corresponding memory cell block.

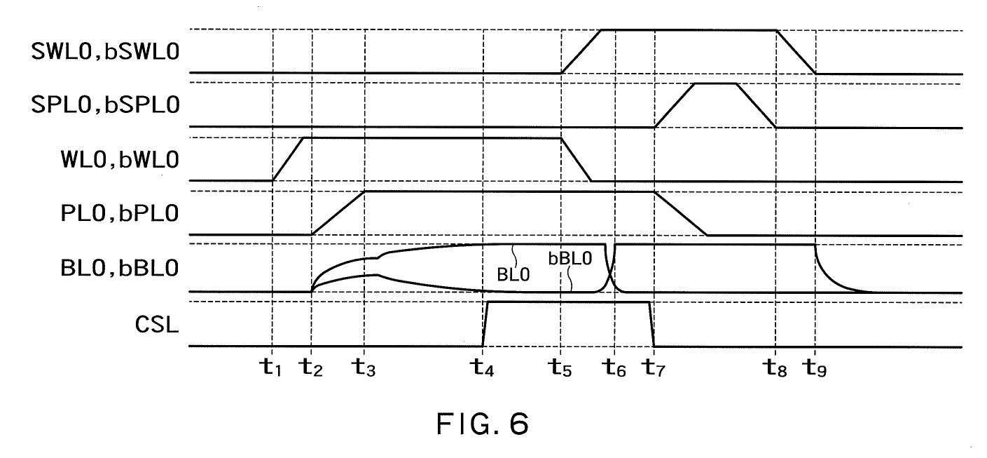

FIG. 6 is a timing chart showing a read operation of the ferroelectric memory according to the first embodiment. According to this operation, two memory cells MC connected to the word lines WL0 and bWL0 and the bit lines BL0 and bBL0 are selected as an example.

When the redundancy block is not used at t1, the word lines WL0 and bWL0 are selected to be logically high. The plate lines PL0 and bPL0 are selected at t2 to be logically high. The data stored in the selected memory cell block is thus transmitted to the bit lines BL and bBL from t2 to t3. The sense amplifier SA detects data through the corresponding bit lines BL and bBL. For example, the bit line BL0 transmits data “1”, while the bit line bBL0 data “0”.

A column selective line CSL shown in FIG. 2 is activated from t4 to t5. The data latched in the sense amplifier SA connected to the bit lines BL0 and bBL0 is transmitted via the local data lines LDL0 and bLDL0 to the ECC circuit. At this time, the column selective line CSL for an unselected column maintains an inactivated state.

When the ECC circuit detects error bits, the ECC circuit writes data with the opposite logic to the read data. The data for correction from the syndrome generating circuit SG is sent to the WL controller WLC and the RD controller RDC as well as the data correcting circuit DCC. The WL controller WLC thus inactivates the selected word lines WL0 and bWL0 at t5. The RD controller RDC activates the spare word lines SWL0 and bSWL0 and the spare plate lines SPL0 and bSPL0. As a result, the data whose logic is inverted at t6 is written in the redundancy block during the restore operation. The data other than the error bits is written in the redundancy block, while maintaining the original logical state.

For example, the bit line bBL0 is logically high and the spare plate lines SPL0 and bSPL0 are logically low from t6 to t7. The data “1” is thus written in the redundancy cell connected to the bit line bBL0. The bit line BL0 is logically low and the spare plate lines SPL0 and bSPL0 are logically high from t7 to t8. The data “0” is thus written in the redundancy cell connected to the bit line bBL0. The corrected data is stored in the redundancy block.

The information the corrected data is written in the redundancy cell is stored in the ferroelectric fuse 10. Accordingly, when the same address is accessed thereafter, the redundancy cell is accessed.

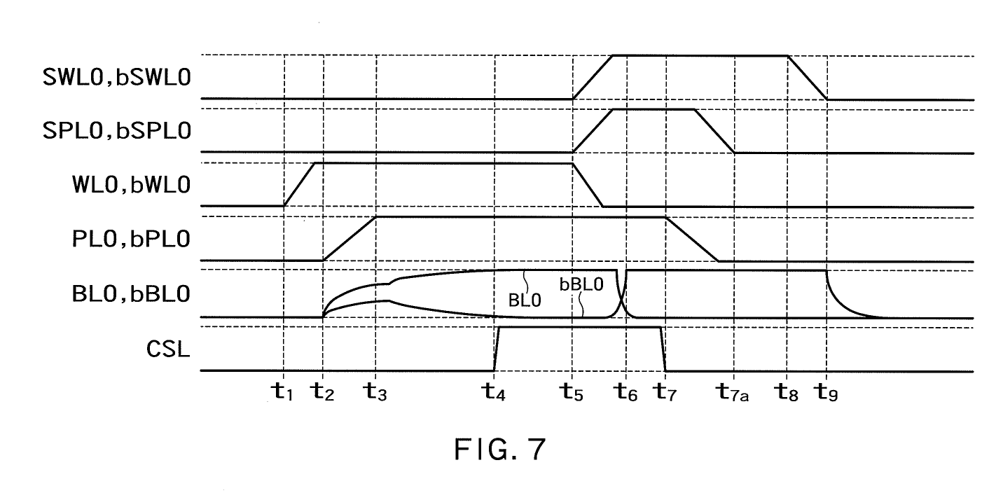

FIG. 7 is a timing chart showing another read operation of the ferroelectric memory according to the first embodiment. In the read operation shown in FIG. 7, timings for writing the data “1” and the data “0” are opposite to those of FIG. 6. Other operations in FIG. 7 are the same as those in FIG. 6.

As shown in FIG. 7, the data “0” is written via the bit line BL0 in the redundancy cell from t6 to t7. The data “1” is written via the bit line bBL0 in the redundancy cell from t7a to t8.

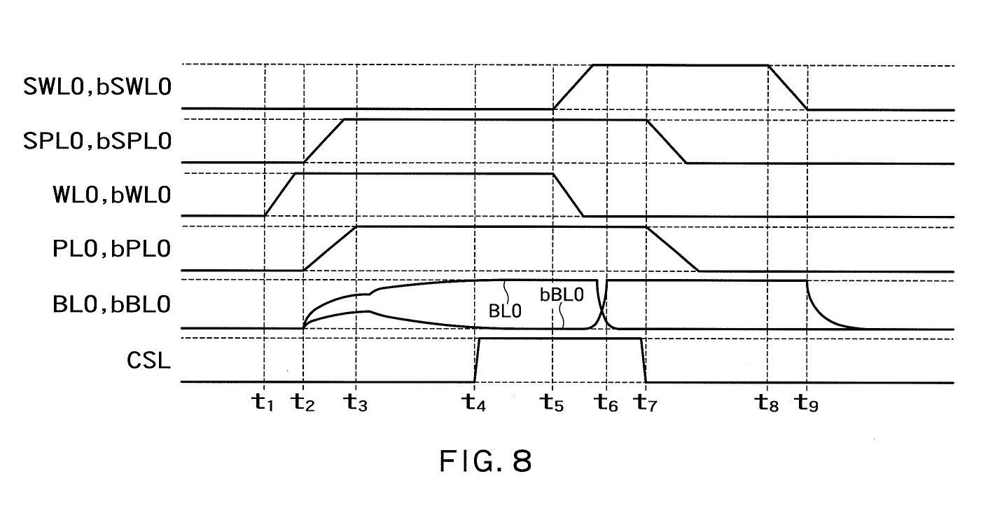

FIG. 8 is a timing chart showing a further read operation of the ferroelectric memory according to the first embodiment. The read operation shown in FIG. 8 operates the plate lines PL and bPL and the spare plate lines SPL and bSPL at the same timing. Other operations shown in FIG. 8 are the same as in FIG. 6.

According to the operation shown in FIG. 8, the spare word lines SWL0 and bSWL0 are selected instead of the selected word lines WL0 and bWL0, so that switching from the memory cell block to the redundancy block is accomplished. That is, because switching between the plate lines PL0 and bPL0 and the spare plate lines SPL0 and bSPL0 is not required, circuits for the WL controller WLC and the RD controller RDC can be simplified.

When error bits exist in the data read from the memory cell array MCA, the ferroelectric memory of the first embodiment writes the data corrected by the ECC circuit in the redundancy cell array RCA during restore. Thus, even if defective memory cells are generated after the ferroelectric memory is received by a user, the correct data can be replaced in the redundancy cell. In this case, changing the polarization state of the ferroelectric fuse 10 can indicate the use of the redundancy block. When the same address is accessed next time, the memory can read the data from the redundancy cell array RCA.

Further, when error bits are generated in the data from the redundancy cell array RCA, the ECC circuit can correct such error bits. By combining the ferroelectric fuse 10 (redundancy cell array RCA) and the ECC circuit, the ferroelectric memory of the first embodiment can handle 2-bit errors generated while a user uses the memory.

### Second Embodiment

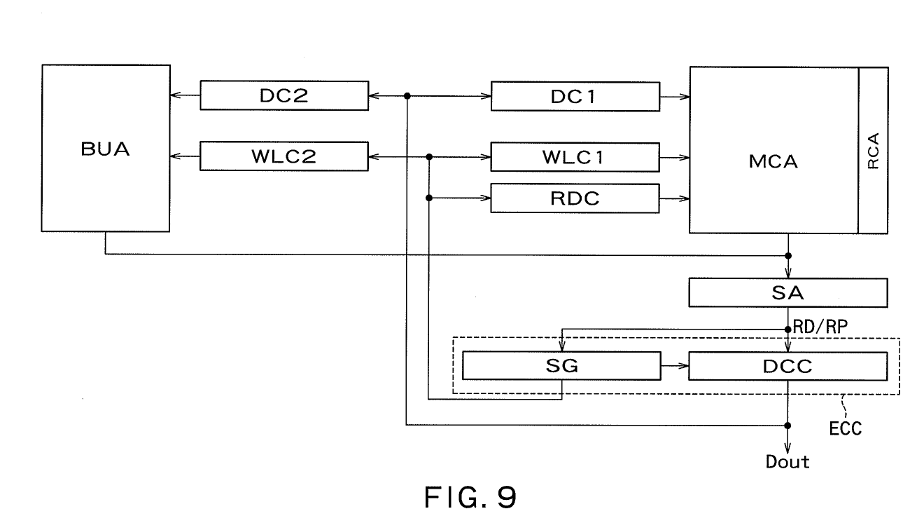

FIG. 9 is a block diagram showing a configuration of a ferroelectric memory according to a second embodiment of the present invention. The second embodiment comprises a backup array BUA in addition to the memory cell array MCA. The backup array BUA has a plurality of memory cells MC arranged two-dimensionally in a matrix like the memory cell array MCA. However, the number of memory cells included in the backup array BUA does not need to be the same as the one in the memory cell array MCA.

Although the backup array BUA does not have the redundancy cell array RCA, it comprises a data controller DC2 and a WL controller WLC2 to access the redundancy array. The backup array BUA shares the sense amplifier SA with the memory cell array MCA. Other configurations of the second embodiment can be identical to those of the first embodiment.

When the ECC circuit detects 1-bit errors, the data in the corresponding memory cell block is not only restored in the memory cell array MCA but also written in the backup array BUA after correction.

When 2-bit errors are generated thereafter in the data of the memory cell block, the ECC circuit can detect such 2-bit errors but cannot correct the 2-bit errors. The data controller DC2 and the WL controller WLC2 then drive the backup array BUA so that the sense amplifier SA detects backup data in the backup array BUA.

Because the data including 1-bit errors is backed up in the backup array BUA as described above, even if 2-bit errors are generated in the memory cell block, the data in the backup array BUA can be used.

More generally, assume that the number of bits corrected by the ECC circuit in a memory cell block is indicated by n. When the number of error bits is equal to n in a memory cell block, the data of the corresponding memory cell block is stored in the backup array as well as the memory cell array. When the ECC circuit detects n+1 bits of error bits, the data is read from the backup array BUA. Thus, the reliability of the ferroelectric memory is improved.

The second embodiment can be combined with the first embodiment. By the combination, even if three or more bit errors are generated in memory cell blocks while a user uses memories, the errors can be handled by the redundancy block and the backup array BUA. For example, when 1-bit errors are generated in a memory cell block, the data is written in the backup array BUA as well as the redundancy block corresponding to the ferroelectric fuse 10. When the same address is accessed thereafter, the sense amplifier SA reads the data stored in the redundancy block. When error bits are generated in the data stored in the redundancy block, the data stored in the backup array BUA is read. Thus, even if the ECC circuit can correct only 1-bit errors, the memory can handle three or more bit errors.

A ferroelectric fuse 20 can be used instead of the laser fuse 20 in the second embodiment. That is, all fuses corresponding to the redundancy blocks can be the ferroelectric fuse 10. Thus, the laser fuse 20 does not need to be formed and the ferroelectric memory can be manufactured easier. Because the ferroelectric fuse 10 has the same configuration as the memory cell MC, processes only for the ferroelectric fuse 10 are not required.

The second embodiment can be applied to a “Series connected TC unit type ferroelectric RAM”. The Series connected TC unit type ferroelectric RAM is a memory which consists of series connected memory cells each having a transistor having a source terminal and a drain terminal and a ferroelectric capacitor inbetween said two terminals. The ferroelectric memory comprises memory cell blocks each of which is configured by connecting serially the memory cells. An end of the memory cell block is connected via a block selective transistor to a bit line. The other end is connected to a plate line.

While the above embodiments use a 2 cell/bit system, a 1 cell/bit system can be used. In the 1 cell/bit system, 1 bit data is stored in one cell and the data stored in that memory cell is detected by the reference voltage.

1. A semiconductor memory device comprising:
a memory cell array comprising a plurality of memory cells, each memory cell comprising a cell transistor and a ferroelectric capacitor connected in serial;
word lines connected to gates of the cell transistors;
bit lines connected to first ends of the memory cells on the cell transistor side;
plate lines connected to second ends of the memory cells on the ferroelectric capacitor side;
a sense amplifier configured to detect data stored in the ferroelectric capacitors;
an error correcting circuit configured to correct an error bit read from the memory cell array;
a redundancy cell array comprising a plurality of redundancy cells, each redundancy cell comprising a cell transistor and a ferroelectric capacitor connected in serial; and
a ferroelectric fuse corresponding to the redundancy cell and configured to indicate whether data is stored in the corresponding redundancy cell, wherein
the data corrected by the error correcting circuit is written in the redundancy cell and a polarization state of the ferroelectric fuse corresponding to that redundancy cell is changed accordingly, when the error bit is read from the memory cell array.

2. The device of claim 1, further comprising:
spare word lines connected to gates of cell transistors of the redundancy cells; and
spare plate lines connected to first ends of the redundancy cells on the ferroelectric capacitor side, wherein
second ends of the redundancy cells on the cell transistor side are connected to any of the bit lines.

3. The device of claim 1, wherein a configuration of the redundancy cell is the same as a configuration of the memory cell.

4. The device of claim 1, further comprising a laser fuse corresponding to the redundancy cell and configured to indicate whether data is stored in the corresponding redundancy cell, wherein
the data of the redundancy cell is used depending on a state of either the laser fuse or the ferroelectric fuse.

5. The device of claim 2, wherein the plate line corresponds to the spare plate line, and the corresponding plate line and spare plate line are driven simultaneously.

6. The device of claim 1, further comprising a backup array configured to store the data of a read block separately from the memory cell array when the number of error bits is equal to N in a read unit block, wherein N indicates the number of bits correctable by the error correcting circuit in the read unit block.

7. A method of driving a semiconductor memory device, the semiconductor memory device comprising:
a memory cell array comprising a plurality of memory cells, each of which comprises a cell transistor and a ferroelectric capacitor which are connected to each other serially;
word lines connected to gates of the cell transistors;
bit lines connected to one ends of the memory cells on the cell transistor side;
plate lines connected to the other ends of the memory cells on the ferroelectric capacitor side;
a sense amplifier configured to detect data stored in the ferroelectric capacitor;
an error correcting circuit configured to correct error bits when such error bits exist in a plurality of pieces of data read from the memory cell array;
a redundancy cell array comprising a plurality of redundancy cells, each of which comprises a cell transistor and a ferroelectric capacitor which are connected to each other serially; and
a ferroelectric fuse corresponding to the redundancy cell and configured to indicate whether data is stored in the corresponding redundancy cell,
the method comprising:
reading from the memory cell by the sense amplifier;
correcting error bits by the error correcting circuit when the error bits exist in the data; and
writing the corrected data in the redundancy cell and changing the polarization state of the ferroelectric fuse corresponding to the redundancy cell.

8. The method of claim 7, wherein the sense amplifier reads data from the redundancy cell during a read operation when the polarization state of the ferroelectric fuse indicates that the data is written in the redundancy cell.

9. The method of claim 7, wherein the semiconductor memory device further comprises a laser fuse corresponding to the redundancy cell and indicating whether data is stored in the corresponding redundancy cell, and
the method further comprises using the data of the redundancy cell without using the data of the memory cell when the state of either the laser fuse or the ferroelectric fuse indicates that the data is written in the redundancy cell.

10. The method of claim 7, wherein the semiconductor memory device further comprises a backup array configured to store data of a read block separately from the memory cell array when the number of error bits is equal to n in a read unit, wherein the n indicates the number of bits correctable by the error correcting circuit in the read unit, and
the method further comprises:
reading data from the backup array when the error correcting circuit detects n+1 bits of error bits in a read unit.
